(19) United States
(12) Patent Application Publication
(10) Pub. No.: US 2019/0113209 A1
(43) Pub. Date: Apr. 18, 2019

(54) LIGHT EMITTING DIODE BACKLIGHT MODULE

(71) Applicant: HON HAI PRECISION INDUSTRY CO., LTD., New Taipei (TW)

(72) Inventors: FENG-YUEN DAI, Tu-Cheng (TW); CHIN-LUNG CHIU, Tu-Cheng (TW); YAO-CHIEN CHUANG, New Taipei (TW); LI-YING WANG HE, Tu-Cheng (TW); YUNG-LUN HUANG, Tu-Cheng (TW)

(21) Appl. No.: 15/796,707

(22) Filed: Oct. 27, 2017

(30) Foreign Application Priority Data
Oct. 18, 2017 (TW) 106135790

(51) Int. Cl. F21V 13/02; F21V 5/04; F21V 19/00; F21V 5/00; F21V 3/04

(52) U.S. Cl. CPC F21V 13/02; F21V 5/04; H01L 25/0753; F21V 5/008; F21V 3/049; F21V 19/0015

(57) ABSTRACT

An LED backlight module comprises a plurality of LED source and a light expansion board. The light expansion board further comprises a substrate and a plurality of lens formed on the substrate. The substrate includes a plurality of receiving holes corresponding to the plurality of LED source for receiving the plurality of LED source therein. The light expansion board includes a material of glass. The light transmittance of the glass is equal to or larger than 95%, the chromatic aberration of the glass is equal to or less than 3/1000, the heat resistance of the glass is equal to or larger than 750° C.

### CROSS-REFERENCE TO RELATED APPLICATIONS

This application claims priority to TW Patent Application No. 106135790 filed on Oct. 18, 2017, the contents of which are incorporated by reference herein.

### FIELD

The subject matter herein generally relates to a light source, especially relates to an light emitting diode (LED) backlight module.

### BACKGROUND

Generally, a backlight module is used as light source for a TV. In order to get a good display effect and save cost in larger size TV, the number of the backlight module is reduced, and an light expansion board and a plurality of lens are mounted corresponding to the backlight modulo to improve the brightness and mix light better. Light emitted from the backlight module is refracted by the light expansion board and the lens, so that the light emitting angle was expanded by the expansion board and the lens.

Usually, most of the light expansion board and the lens are separated molding and are made of the Polycarbonate or polymethyl methacrylate. However, when the TV works in a long time, the backlight module would to generate so much thermal energy that the expansion board and the lens may be accelerated aging. Thus, a display of the TV is easy to happen image distortion.

### BRIEF DESCRIPTION OF THE DRAWINGS

Implementations of the present technology will now be described, by way of example only, with reference to the attached figures.

FIG. 1 is an isometric view of an LED backlight module of the present disclosure.

FIG. 2 is a cross-sectional view of the LED backlight module of FIG. 1 along the II-II line.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts have been exaggerated to better illustrate details and features of the present disclosure. The description is not to be considered as limiting the scope of the embodiments described herein.

Several definitions that apply throughout this disclosure will now be presented. The term “comprising” means “including, but not necessarily limited to”; it specifically indicates open-ended inclusion or membership in a so-described combination, group, series and the like. The term “coupled” is defined as connected, whether directly or indirectly through intervening components, and is not necessarily limited to physical connections. The connection can be such that the objects are permanently connected or releasably connected.

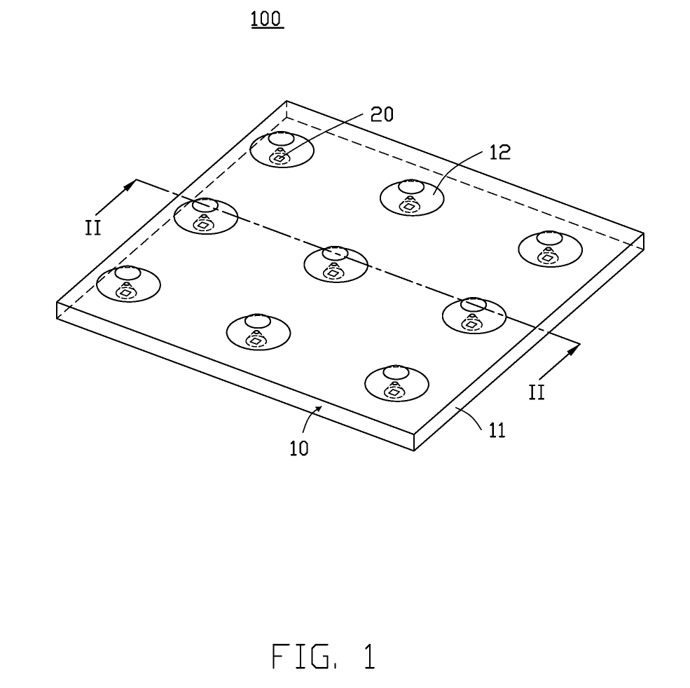

Referring to FIG. 1, an LED backlight module 100 of the present disclosure includes a light expansion board 10 and a plurality of LED source 20.

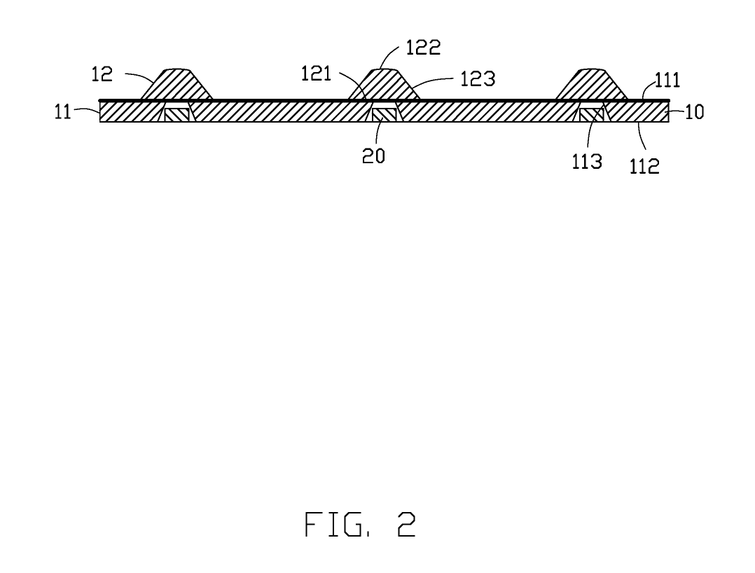

Also referring to FIG. 2, the light expansion board 10 is a material of glass. The glass satisfies the following demand: light transmittance is equal to or larger than 95%; chromatic aberration is equal to or less than 3/1000; heat resistance is equal to or larger than 750° C.

Further, the light expansion board 10 includes a substrate 11 and a plurality of lens 12 formed on the substrate 11. The plurality of lenses 12 and the substrate 11 are one body structure that manufactured by the glass melt molding and then cooling. The plurality of the lenses 12 corresponds to the plurality of LED sources 20.

The substrate 11 is a flat board. The substrate 11 has a first surface 111 and a second surface 112 opposite to the first surface 111. The first surface 111 of the substrate 11 is a rough surface that is manufactured by atomization sandblasting processing.

The substrate 11 further forms a plurality of receiving holes 113. The plurality of receiving holes 113 extends from the second surface 112 to the first surface 111. The plurality of receiving holes 113 corresponds to the plurality of LED source 20 and receives the plurality of the LED sources 20 therein.

In the exemplary embodiment, each receiving hole 113 is trapezoid shaped. A diameter of each receiving holes 113 increases from the first surface 111 to the second surface 112 of the substrate 11.

The plurality of the lens 12 extends upward from the first surface 111 of the substrate 11. Specifically, the plurality of lenses 12 has a bottom surface 121 connected with the first surface 111, a top surface 122 opposite to the bottom surface 121, and a side surface 123 connected with the bottom surface 121 and the top surface 122. The bottom surface 121 is a rough surface that is manufactured by atomization sandblasting processing. The top surface 122 is a spherical surface. The side surface 123 is a conical surface. An area of the bottom surface 121 is larger than an area of the top surface 122. A cross-sectional width of the bottom surface 121 is larger than the largest aperture of the receiving hole 113.

In the exemplary embodiment, the bottom surface 121 of the lens 12 is coplanar with the first surface 111 of the substrate 11.

While the LED backlight module 100 is working, light emitted from the LED source 20 is diffused by the plurality of lenses 12 to exit. Because of the rough surface of the bottom surface 121 of the lens 12, so the light emitted from the LED source 20 is refracted by the bottom surface 121 and exits from the top surface 122 of the lens 12. The bottom surface 121 and the top surface 122 expand an emitting angle of the light emitted from the LED source. The bottom surface 121 further shortens the mixed light distance between different LED sources 20. Further, light exits from the top surface 122 and part of the light was reflected by the top surface 122 toward to the bottom surface 121, thus, the bottom surface 121 can refract and reflect the light to exit from the top surface 122.

In the LED backlight module 100 of the present disclosure, the plurality of lenses 12 and the substrate 11 are one body structure that is manufactured by the glass melt molding and then cooling. Thus, the heat resistance of the light expansion board 10 is improved. So the light expansion board 10 slows down deterioration thereof due to heat from the LED source 20. The LED backlight module 100 has steady and even brightness.

Further, the bottom surface 121 of the lens 12 is coplanar with the first surface 111 of the substrate 11 and is a rough surface that is manufactured by atomization sandblasting processing. Thus, the bottom surface 121 further shortens the mixed light distance between different LED sources 20. So the LED backlight module 100 not only has steady and even brightness, but also has a thinner thickness.

The embodiments shown and described above are only examples. Many details are often found in the art such as the other features of LED backlight module. Therefore, many such details are neither shown nor described. Even though numerous characteristics and advantages of the present technology have been set forth in the foregoing description, together with details of the structure and function of the present disclosure, the disclosure is illustrative only, and changes can be made in the detail, including in matters of shape, size and arrangement of the parts within the principles of the present disclosure up to, and including the full extent established by the broad general meaning of the terms used in the claims. It will therefore be appreciated that the embodiments described above can be modified within the scope of the claims.

What is claimed is:

1. A light emitting diode (LED) backlight module, comprising:
a plurality of LED source;
a light expansion board, comprising:
a substrate having a plurality of receiving holes corresponding to the plurality of LED source for receiving the plurality of LED sources therein;
a plurality of lens formed on the substrate;
wherein the light expansion board includes a material of glass, a light transmittance of the glass is equal to or larger than 95%, a chromatic aberration of the glass is equal to or less than 3/1000, the heat resistance of the glass is equal to or larger than 750° C.

2. The LED backlight module of claim 1, wherein the plurality of lenses and the substrate are a one body structure that is manufactured by the glass melt molding and then cooling.

3. The LED backlight module of claim 1, wherein the substrate 11 has a first surface and a second surface opposite to the first surface, the plurality of receiving holes extends from the second surface 112 to the first surface of the substrate.

4. The LED backlight module of claim 3, wherein the first surface of the substrate is a rough surface that is manufactured by atomization sandblasting processing.

5. The LED backlight module of claim 3, wherein each receiving hole is trapezoid shaped, a diameter of each receiving holes increases from the first surface to the second surface of the substrate.

6. The LED backlight module of claim 3, wherein the plurality of lenses extends upward from the first surface of the substrate, each of the plurality of lens has a bottom surface connected with the first surface, a top surface opposite to the bottom surface, and a side surface connected with the bottom surface and the top surface.

7. The LED backlight module of claim 6, wherein the bottom surface is coplanar with the first surface of the substrate and is a rough surface that is manufactured by atomization sandblasting processing.

8. The LED backlight module of claim 6, wherein the top surface is a spherical surface, and the side surface is a conical surface.

9. The LED backlight module of claim 6, wherein an area of the bottom surface is larger than an area of the top surface.

10. The LED backlight module of claim 6, wherein a cross-sectional width of the bottom surface is larger than the largest aperture of the receiving hole.
